(19) United States
(12) Patent Application Publication
(10) Pub. No.: US 2018/0033957 A1
(43) Pub. Date: Feb. 1, 2018

(54) METHOD TO MAKE MAGNETIC RAMDOM ACCESSS MEMROY ARRAY WITH SMALL FOOTPRINT

(71) Applicant: Shanghai CiYu Information Technologies Co., LTD, Fremont, CA (US)

(72) Inventors: Yun Sen Zhang, Shanghai (CN); Rongfu Xiao, Dublin, CA (US); Yimin Guo, Fremont, CA (US); Jun Chen, Fremont, CA (US)

(73) Assignee: Shanghai CiYu Information Technologies Co., LTD, Shanghai (CN)

(21) Appl. No.: 15/219,286

(22) Filed: Jul. 26, 2016

(51) Int. Cl. H01L 43/12; H01L 43/08

(52) U.S. Cl. CPC H01L 43/12; H01L 43/08; H01L 27/222

(57) ABSTRACT

This invention is about a method to make magnetic random access memory with small footprint directly on CMOS VIA with a self-aligned etching process. The process schemes of the method proceeds as: (1) Etch MTJ and BE using one or more of RIE and/or IBE processes with Ta as hard mask; (2) Etch BE using one or more of RIE and/or IBE processes with Ta & sidewall protection layer on MTJ as hard mask; and (3) Etch a part of MTJ and BE using one or more of RIE and/or IBE processes with Ta & sidewall protection layer on top portion of MTJ as hard mask. All the three schemes lead the BE to be self-aligned to MTJ cells, the photo overlay margin is not necessary and circuits could be made extremely small with lower manufacturing cost; The invention also provides schemes to prevent the electrical shorting across the tunnel barrier layer. Through trimming and sidewall protection deposition process, device performance and electrical/magnetic properties could be greatly improved.

### BACKGROUND OF THE INVENTION

### 1. Field of the Invention

This invention relates generally to a method to make magnetic random access memory with small footprint using a self-aligned etching process.

### 2. Description of the Related Art

In recent years, magnetic random access memories (hereinafter referred to as MRAMs) using the magneto resistive effect of ferromagnetic tunnel junctions (also called MTJs) have been drawing increasing attention as the next-generation solid-state nonvolatile memories that can also cope with high-speed reading and writing. A ferromagnetic tunnel junction has a ferromagnetic/insulator/ferromagnetic sandwich structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magneto resistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magneto resistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magneto resistive element. As the volume of the magnetic layer forming the recording layer is smaller, the injected spin-polarized current to write or switch can be also smaller.

Further, as in a so-called perpendicular spin-transfer torque magnetic random access memories (pSTT-MRAM), both of the two magnetic layers have easy axis of magnetization in a direction perpendicular to the film plane due to their strong magnetic crystalline anisotropy (shape anisotropies are not used), and accordingly, the device shape can be made smaller than that of an in-plane magnetization type.

In the meantime, since the switching current requirements reduce with decreasing MTJ element dimensions, pSTT-MRAM has the potential to scale nicely at the most advanced technology nodes. To make smaller cells, a better way is to build the MTJ cell directly on CMOS VIA in between a BE. Currently, to pattern MTJ cells and bottom electrodes, separated photo masks have to be used, one is for MTJ cells and the other is for BEs, the photolithographic overly error of MTJ and BE could not be ignored when the dimensional feature decreased which would reduce the yield of MRAM, meanwhile, if using more photomasks, the complexity of process integration and manufacturing cost would be increased. Separate patterning is not also mandatory for STT-MRAM.

Nowadays, there are two methods to etch the magnetic and refractory materials during MRAM manufacturing: one is Ion Beam Etching (IBE) and the other Reactive Ion Etching (RIE), as for the etching by-product is non-volatile, the conductive by-product residues would be deposited on the sidewall which would lead to the electrical shorting across the barrier layer, meanwhile, the chemical and physical damage could not be avoided, thus, the magnetic/electronic properties of MRAM devices would be influenced.

### BRIEF SUMMARY OF THE PRESENT INVENTION

This invention is about a method to make magnetic random access memory with small footprint directly on CMOS VIA using a self-aligned etching process. In embodiments, the MTJ patterning are defined by a single litho-etch (LE) or double litho-etch (LELE) process, continuously, Reactive ion etching (RIE) is used in etching of hard mask (HM) stack, then the MTJ stack and BE stack are etched as specified in various embodiments which include selection of (1) Etch MTJ stack and BE stack using one or more of RIE and/or IBE processes with Ta as hard mask; (2) Etch BE stack using one or more of RIE and/or IBE processes with Ta & sidewall protection layer on MTJ as hard mask; and (3) Etch a part of MTJ stack and BE stack using one or more of RIE and/or IBE processes with Ta & sidewall protection layer on top portion of MTJ as hard mask. All of the embodiments make the BE stack self-aligned to MTJ stack, these processes in the embodiments of invention is named as self-aligned etching process.

Embodiments of the invention also provide process schemes to etch the MTJ stack and BE stack without electrical shorting path formation across the tunnel barrier layer along sidewall. The embodiments include the selection of (1) IBE trim the exposed sidewall edge after a whole MTJ stack etching process; (2) Deposit a protection layer after a partially MTJ stack etching process; or (3) combination of IBE trimming and deposition after a whole MTJ stack etching process. Through removing the re-deposition and/or damage layer on the exposed sidewall edge, through an etching process stop at the tunnel barrier layer and then with a dielectric protection layer encapsulated the top portion of MTJ stack, electrical shorting across the tunnel barrier has been eliminated and the electrical/magnetic properties of the MRAM cells have been greatly improved, such us: the improvement of the Tunneling Magnet-Resistance (TMR) and so on, thus, the yield of MRAM circuits could be enhanced.

Comparing to the prior arts in which the BE patterning and MTJ patterning are defined by separated photomasks, there is a benefit in defining MTJ and BE patterning using the same photomask in which one photolithographic process and the related deposition, planarization and cleaning processes etc., could be eliminated, which could reduce the complexity of process integration and manufacturing cost. Meanwhile, there is no BE and MTJ photo overlay error, the overlay margin is not necessary, this is better for the scalability of manufacturing of MRAM circuits.

### BRIEF DESCRIPTION OF THE DRAWINGS

For a more complete understanding of present disclosure, reference is now made to the following description taken in conjunction with the accompanying drawing.

FIG. 1 illustrates the diagram of process flow chart to make MTJ and BE according to embodiments of the invention.

FIG. 2 is a cross sectional view of polished CMOS substrate with VIA.

FIG. 3A is a cross sectional view after BE stack, MTJ stack and HM stack deposition.

FIG. 3B illustrates a cross sectional view of MTJ stack.

FIG. 4 is a cross sectional view after MTJ patterning definition and HM etching.

FIG. 5A is a cross sectional view after MTJ and BE etching in embodiment one.

FIG. 5B is a cross sectional view after exposed edge trimming in embodiment one.

FIG. 5C is a cross sectional view after encapsulation in embodiment one.

FIG. 5D is a cross sectional view after dielectric refill and CMP in embodiment one.

FIG. 6A is a cross sectional view after MTJ etching in embodiment two.

FIG. 6B is a cross sectional view after exposed edge trimming in embodiment two.

FIGS. 6C and 6D are cross sectional views of one time of self-aligned to etch BE in embodiment two, 6C-deposition; 6D-etching;

FIGS. 6E, 6F, 6G and 6H are cross sectional views of two times self-aligned to etch BE in embodiment two, 6E-the first deposition; 6F-the first etching; 6G-the second deposition and 6H-the second etching.

FIGS. 6I and 6J are cross sectional views after dielectric refill and CMP in embodiment two, 6I-one time of self-aligned etching process; 6J-two times of self-aligned etching process.

FIG. 7A is a cross sectional view after MTJ stack partially etched in embodiment three.

FIGS. 7B and 7C are cross sectional views of one time self-aligned to etch MTJ and BE stacks in embodiment three, 7B-deposition; 7C-etching.

FIGS. 7D, 7E, 7F, 7G, 7H and 7I are cross sectional views of three time self-aligned to etch MTJ and BE stacks in embodiment three, 7D-the first deposition; 7E-the first etching; 7F-the second deposition, 7G-the second etching, 7H-the third deposition and 7I-the third etching.

FIGS. 7J and 7K are cross sectional views after dielectric refill and CMP in embodiment three, 7J-oone time of self-aligned etching process; 7K-three times of self-aligned etching process.

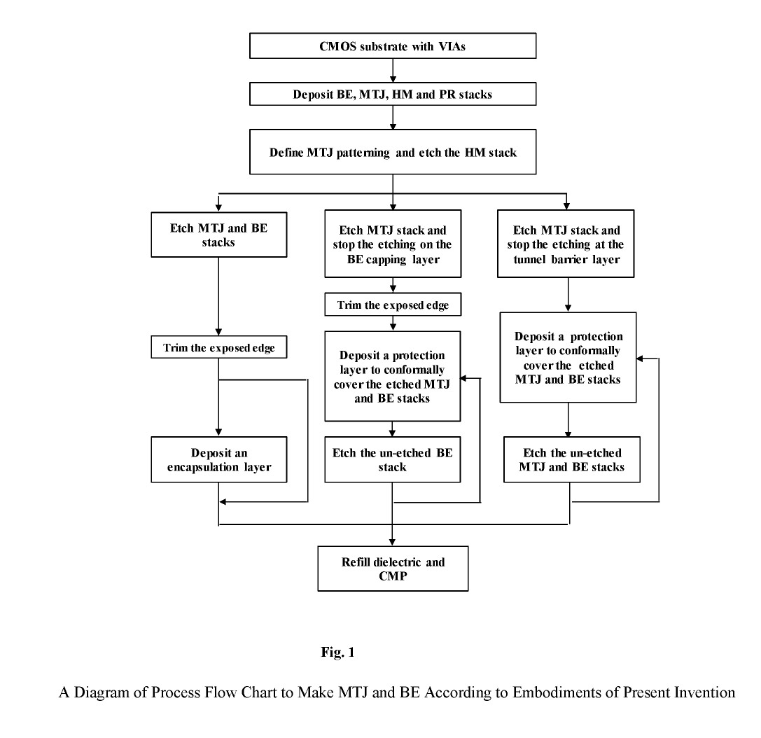

### DETAILED DESCRIPTION OF THE INVENTION

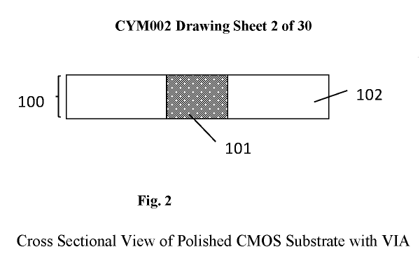

The process flow is outlined in FIG. 2. There are three different approaches to make MRAM cells. The exemplary embodiment will be described hereinafter with reference to the companying drawings. The drawings are schematic or conceptual, and the relationships between the thickness and width of portions, the proportional coefficients of sizes among portions, etc., are not necessarily the same as the actual values thereof. The figures and description herein reference only one cell of the plurality of cells that will be typically be fabricated simultaneously on a single wafer.

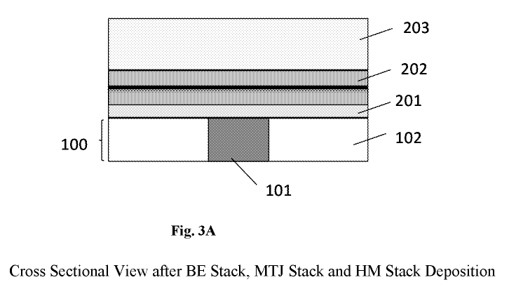

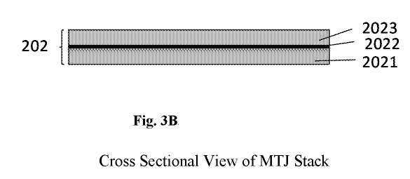

At first, the incoming substrate (100) (FIG. 3) has the CMOS transistor control unit (not shown here) already built in with its Inter-Metal Dielectric (IMD) (101) and Cu or W filled VIA (102) ready for bottom electrode (BE) film deposition. Before deposition, make sure that the polished IMD (101) and VIA (102) surface should be co-planar and with a good surface roughness.

Secondly, as shown in FIG. 3A, the BE stack (201) deposition begins with BE seed layer, such as Ta, TaN, Ti or TiN (0.5 nm-5 nm) (not shown in the figure) followed by a portion (5nm-30nm) of the main conducting layer, such as Ru, Cu, CuN, Mo or W and an optional BE capping layer or MTJ etching stop layer which is made of Ta, TaN, W or WN (0 nm-10 nm) is deposited. After BE (201) deposition, the MTJ stack (202) is continuously deposited by Physical Vapor Deposition (PVD) without breaking the vacuum environment or interrupted by a Chemical Mechanical Polish (CMP) process for surface roughness further improvement between BE stack (201) and MTJ stack (202).

The deposition of MTJ stack (202) begins with a magnetic reference element stack (2021), such as: as [X/Co]nRuCo[X/Co]m/Y/CoFeB/where X is selected from Pt, Pd or Ni and Y is selected from Ta, W, or Mo, then an oxide tunnel barrier layer (2022), such us: MgO or MgZnO, and a magnetic memory (or recording) element (2023), such us: CoFeB and/or CoFe, or a reversed stack of magnetic memory layer, tunnel barrier and memory reference elements, as shown in FIG. 3B. The MTJ stack (202) is a perpendicular magnetic tunneling junction (pMTJ) or in-plane magnetic tunneling junction (iMTJ). The total thickness of the MTJ stack (202) is betweenl5nm and 40nm. For a better MTJ stack (202) crystal structure formation, generally, before MTJ stack (202) deposition, a thin seed layer could be deposited first of all. Also, after MTJ stack (202) deposition, a capping layer or etching stop layer could be further deposited which is made of Mg, Hf, Zr, Ti, Ru or their oxide MgO, HfO, ZrO, TiO, RuO.

After MTJ stack (202) has been deposited, a HM stack (203) is deposited with a Ta single layer, Ta/Si-dielectric bi-layer or Ta/C/Si-dielectric tri-layer. The thickness of Ta film is between 40 nm and 100 nm. Then, a PR stack is deposited with a BARC/PR bi-layer, or OPL/ARC/PR tri-layer in which BARC refers to bottom anti-reflective coating, PR refers to photo resist, ARC refers to anti-reflective coating and OPL refers to organic planarization layer.

Next, define the MTJ (202) patterning using a single litho-etch (LE) or double litho-etch (LELE) process. Currently, the mainstream photo-lithography technology for patterning definition is using 193 nm ArF UV light, for smaller MRAM manufacturing, such us: the critical dimension (CD) of MTJ cells is less than 40 nm, other technology should be used, such us: EUV, LELE or E-beam, etc. In the embodiments of the invention, depending on MRAM cell density, two approaches are used for the patterning definition by the mainstream lithographic technology of nowadays, one approach is LE for low density MRAM manufacturing, such us: CD is 40 nm or bigger than 40 nm, the other approach is LELE for high density MRAM manufacturing, such us: CD is less than 40 nm.

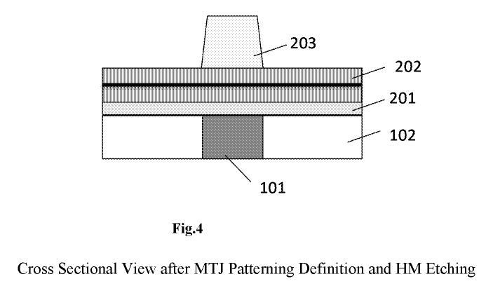

Then, as shown in FIG. 4, the HM stack (203) is etched by a series of RIEs using fluorine (such us: CF4 or SF6) or C12 based gases for Ta, fluorine based gases for Si-dielectric, and oxygen for C layer. After etching, the HM residue would be removed by one or several etch gases selected from CF4, NF3, SF6, O2, N2, H2 or H2O.

Further processes are described in the following Embodiment One, Two, Three depending on which approach is used. The first approach is to etch MTJ stack(202) and BE stack (201) continuously using one or more of RIE and/or IBE processes with Ta as hard mask; The second approach is to first stop at the bottom of MTJ (or on BE capping layer) and etch BE stack (201) using one or more of RIE and/or IBE processes with Ta & sidewall protection layer on MTJ as hard mask; The third approach is to first stop at the oxide barrier layer and etch the remaining part of MTJ (202) and BE (201) stacks using one or more of RIE and/or IBE processes with Ta & sidewall protection layer on top portion of MTJ as hard mask. All of the embodiments make the BE (201) self-aligned to the MTJ cells (202), these processes in the embodiments of invention is named as self-aligned etching process.

### Embodiment One

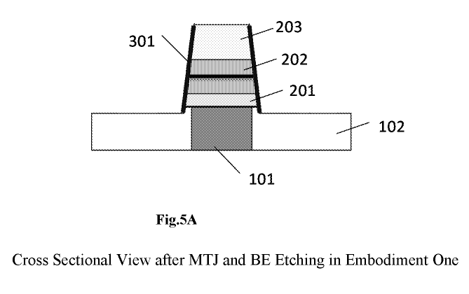

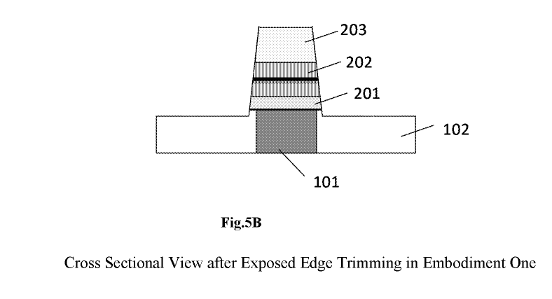

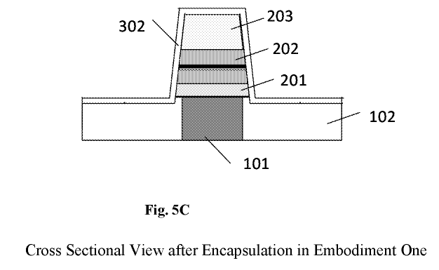

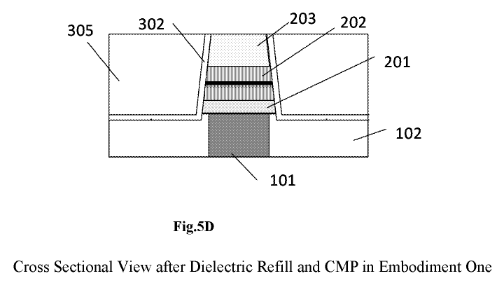

Following from the above HM stack (203) etch process, as shown in FIG. 5A, the MTJ (202) and BE (201) stacks are etched using one or more of RIE and/or IBE processes with Ta as hard mask (self-aligned etching process). A thin layer of IMD (101) under BE stack (201) should be etched away to prevent the electrical shorting between the bottom electrodes nearby.

The RIE etch process is taken place in an Inductively Coupled Plasma (ICP) or Capacitively Coupled Plasma (CCP) chamber with a precisely controllable vacuum range from 1 mTorr to 100 mTorr; The source power is adjusted from 200 watt to 3000 watt, the bias power is adjusted from 100 watt to 1500 watt; The main etchant of RIE could be selected from CH4/H2, CO/NH3, CH3OH or C2H5OH with the gas flow rate from 5 sccm to 100 sccm, optionally, the RIE etchant could be also added by some other chemistries, such us: Ar, Kr and Xe etc., with the gas flow rate from 10 sccm to 200 sccm; The temperature range of Electrostatic Chuck (ESC) is from 20° C. to 300° C. which could be used for wafer temperature controlling.

The Ion beam in the IBE could be selected as perpendicular or tilted to the wafer substrate, such us: 5° or 10°; The ion beam gas could be selected from Ar, Ke or Xe etc., with the gas flow rate from 10 sccm to 200 sccm, such us: 10 sccm, 30 sccm, 50 sccm, 100 sccm or 200 sccm, additionally, small flow rate N2 or O2 could be also further added into the etch chemistry; The source power is adjusted from 100 watt to 3000 watt, the acceleration voltage is adjusted from 50 volt to 1000 volt; The rotation speed of wafer stage is from 0 rpm to 60 rpm, such us: 0 rpm, 30 rpm or 60 rpm.

The etching endpoint detection signal could be selected from optical emission spectroscopy (OES) or secondary ion mass spectroscopy (SIMS) which could help determine ending of etching using the changed signal at the interface of BE (201) and IMD (101).

After the etching process, the exposed edge of the etched MTJ (202) and BE (201) stacks is trimmed by a low energy IBE to remove the re-deposition and/or damage layer (301), as shown in FIG. 5B.The trimming gas of IBE could be selected from Ar, Kr or Xe; The incident angle to the wafer stage could be selected from 0° to 90°, such us: 5° or 15°, etc.; The rotation speed of wafer stage is from 0 rpm to 60 rpm, such us: 15 rpm or 45 rpm. Optionally small flow of O3 or O2 could be also further used after the IBE trimming to oxidize any remaining metallic particles near the MTJ barrier.

Then, as shown in FIG. 5C, as an optional process, a dielectric encapsulation layer (302) is deposited on the exposed area of etched Ta HM (203), MTJ (202) and BE (201) stacks using, for example, CVD or ALD technology. The encapsulation layer is made of a dielectric, such us: SiO2, SiON, SiN, SiC, SiCN MgO or Al2O3, if it is possible, the CVD or ALD process should be immediately executed after the trimming process without breaking the vacuum.

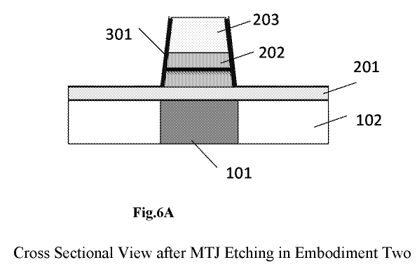

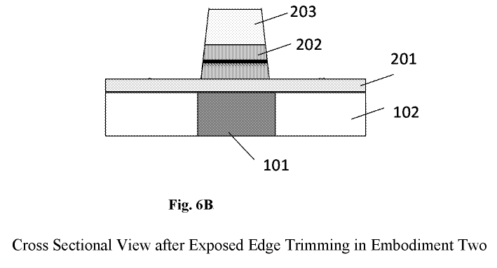

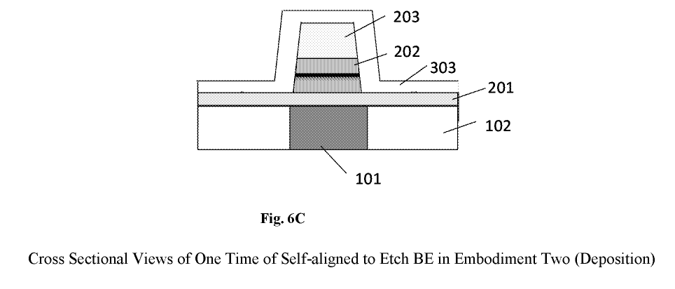

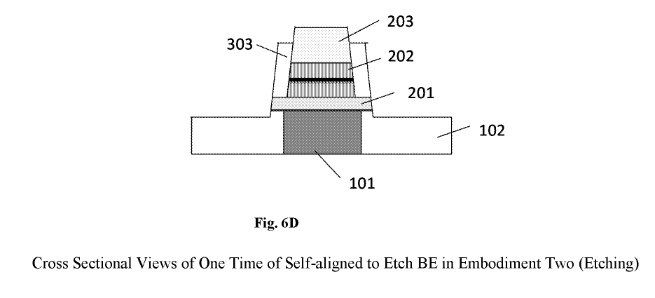

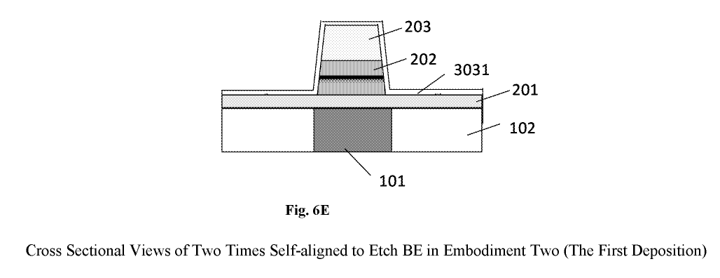

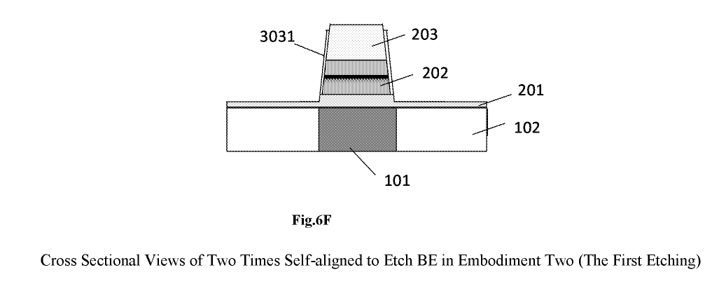

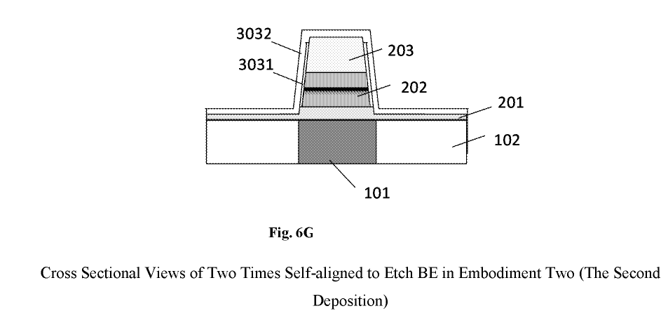

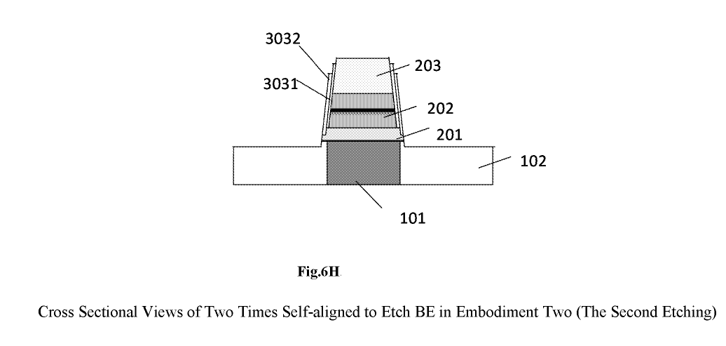

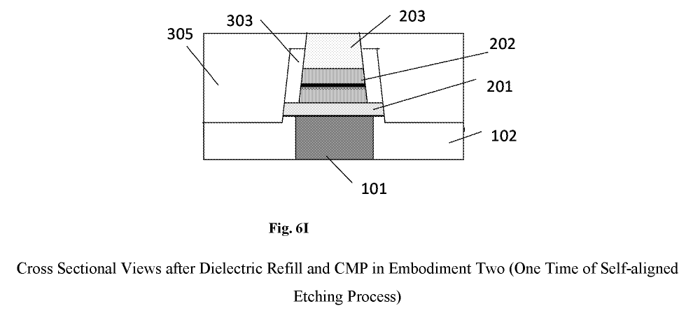

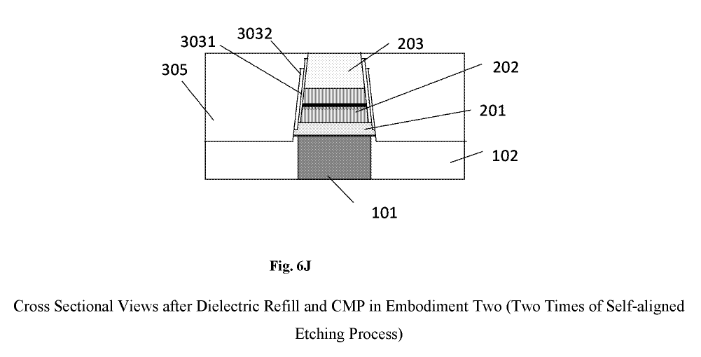

Finally, as shown in FIG. 6D, a dielectric layer (305) is refilled in the etched area of Ta HM (203), MTJ (202) and BE (201) using CVD technology with SiN, SiO2 or SiON, after that, the dielectric layer (305) is polished to the top of Ta HM layer (203) using chemical mechanical polishing (CMP) method.

### Embodiment Two

Following from the above HM stack (203) etch process, as shown in FIGS. 6A and 6B, the MTJ stack (202) is etched and the etching is stopped on the capping layer of BE (201), then a low energy IBE trimming is used to remove the re-deposition and/or damage layer (301) on the exposed edge.

The etchant of MTJ stack (202) RIE could be selected from CO/NH3, CH3OH, CH3OH/Ar or C2H5OH, the endpoint trigger signal could be selected from OES or SIMS which could help to determine ending of etching using the changed signal at the interface of MTJ (202) and BE (201) capping layer. The trimming gas of IBE could be selected from Ar, Kr or Xe; The incident angle to the wafer stage could be selected from 0° to 90°, such us: 5° or 15°, etc.; The rotation speed of wafer stage is from 0 rpm to 60 rpm, such us: 15 rpm or 45 rpm. Optionally small flow of O3 or O2 could be also further used after the IBE trimming to oxidize any remaining metallic particles near the MTJ barrier.

Next, as shown in FIGS. 6C, 6D, 6E, 6F, 6G and 6G, BE stack (201) is etched using one or more of RIE and/or IBE processes with Ta & sidewall protection layer on MTJ as hard mask (self-aligned etching process). A thin layer of IMD (101) under BE stack (201) should be etched away to prevent the electrical shorting between the bottom electrodes nearby.

The self-aligned etching process of BE stack (201) is divided into two sub-processes (1) Deposition: deposit a protection layer to conformally cover the etched Ta HM (203), MTJ stack (202) and BE stack (201) using CVD or ALD; (2) Etching: etch the bottom of the protection layer and un-etched BE stack (201) using IBE or RIE; The (1) Deposition/(2) Etching flow could be repeated until the exposed BE is completely etched away.

The protection layer is a dielectric, such us: SiO2, SiON, SiN, SiCN, SiC, MgO or Al2O3; The thickness is between 2 nm and 50 nm.

The RIE etch process is taken place in an Inductively Coupled Plasma (ICP) or Capacitively Coupled Plasma (CCP) chamber with a high precise controllable vacuum range from 1 mTorr to 100 mTorr; The source power is adjusted from 200 watt to 3000 watt, the bias power is adjusted from 100 watt to 1500 watt; The main etchant of RIE could be selected from CH4/H2, CO/NH3, CH3OH or C2H5OH with the gas flow rate from 5 sccm to 100 sccm, optionally, the RIE etchant could be also added by some other chemistries, such us: Ar, Kr and Xe etc., with the gas flow rate from 10 sccm to 200 sccm; The temperature range of Electrostatic Chuck (ESC) is from 20° C. to 300° C. which could be used for wafer temperature controlling.

The Ion beam in the IBE could be selected as perpendicular or tilted to the wafer substrate, such us: 5° or 10°; The ion beam gas could be selected from Ar, Ke or Xe etc., with the gas flow rate from 10 sccm to 200 sccm, such us: 10 sccm, 30 sccm, 50 sccm, 100 sccm or 200 sccm, additionally, small flow rate N2 or O2 could be also further added into the etch chemistry; The source power is adjusted from 100 watt to 3000 watt, the acceleration voltage is adjusted from 50 volt to 1000 volt; The rotation speed of wafer stage is from 0 rpm to 60 rpm, such us: 0 rpm, 30 rpm or 60 rpm.

The etching endpoint trigger signal could be selected from OES or SIMS which could help determine ending of etching using the changed signal at the interface of BE (201) and IMD (101).

An exemplary embodiment of etching BE stack (201) using self-aligned etching process is described as below: (1) Deposition: as shown in FIG. 6C, deposit a protection layer (303) to conformally cover the etched Ta HM (203), etched MTJ (202) stack and BE stack (201); (2) Etching: as shown in FIG. 6D, etch the bottom of protection layer (303) and BE stack (201) with some IMD (101) be etched away.

Another embodiment of etching BE (201) using self-aligned etching processes described as below: (1) The first Deposition: as shown in FIG. 6E, deposit a first protection layer (3031) to conformally cover the etched Ta HM (203), etched MTJ stack (202) and BE (201) stack; (2) The first Etching: as shown in FIG. 6F, etch the bottom of first protection layer (3031) and BE stack (201); (3) The second Deposition: as shown in FIG. 6G, deposit a second protection layer (3032) to conformally cover the etched Ta HM (203), etched MTJ stack (202), BE stack (201) and the un-etched first protection layer (3031); (4) The second Etching: as shown in FIG. 6H, etch the bottom of second protection layer (3032) and the un-etched BE stack (201) using IBE or RIE with some IMD (101) be etched away.

Finally, as shown in FIGS. 6I and 6J, a dielectric layer (305) is refilled in the etched area of Ta HM (203), MTJ (202) and BE (201) using CVD technology with SiN, SiO2 or SiON, after that, the dielectric layer (305) is polished to the top of Ta HM layer (203) using CMP.

### Embodiment Three

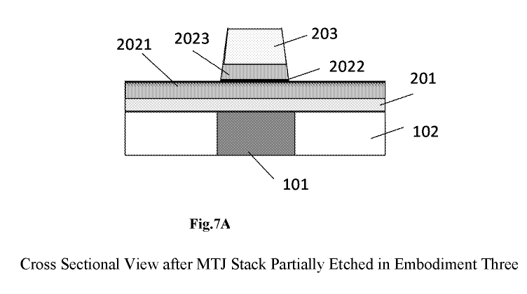

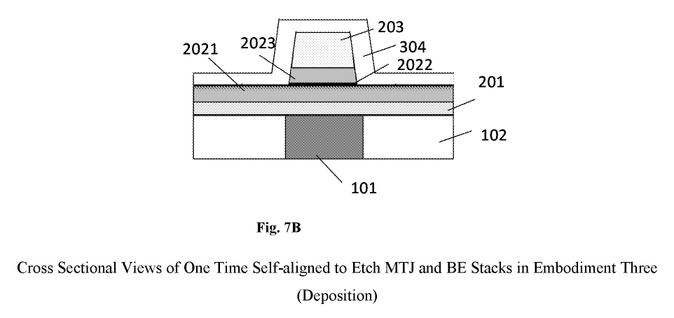

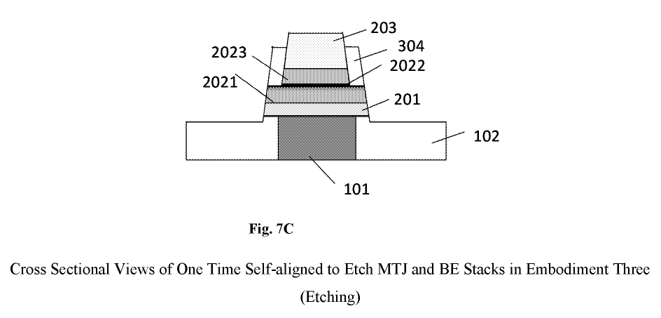

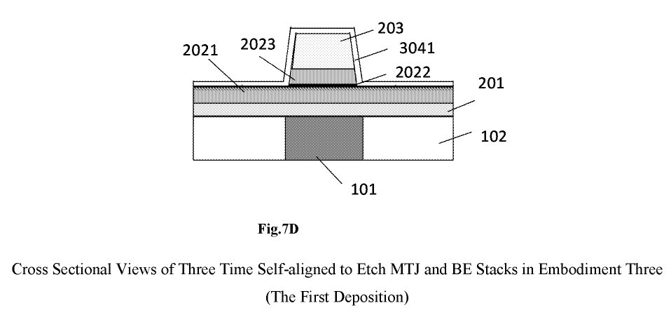

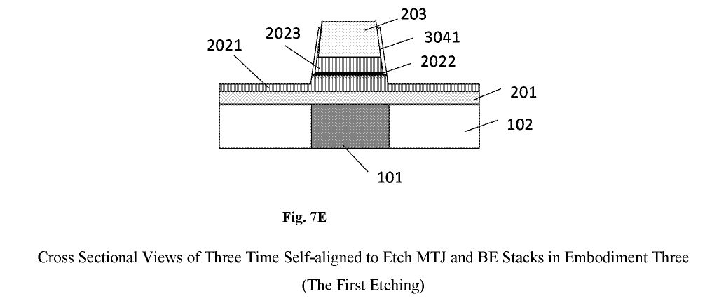

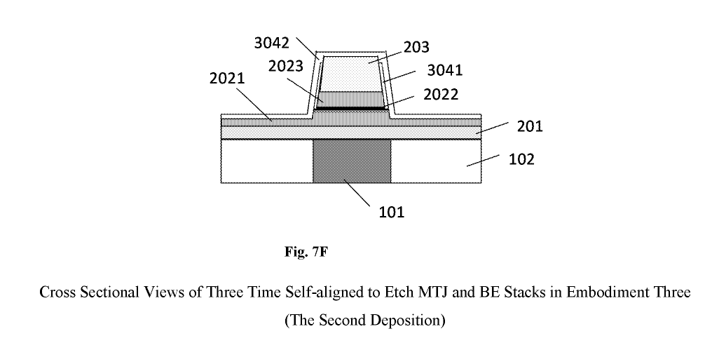

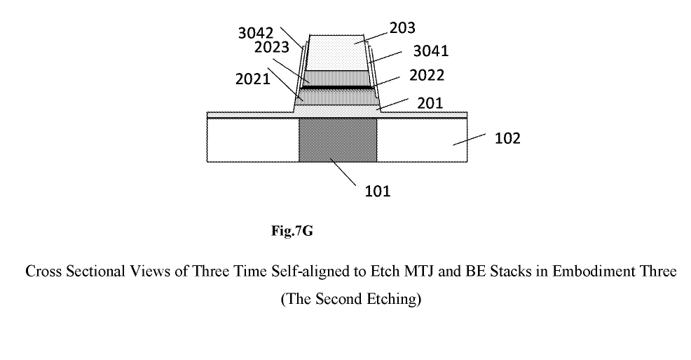

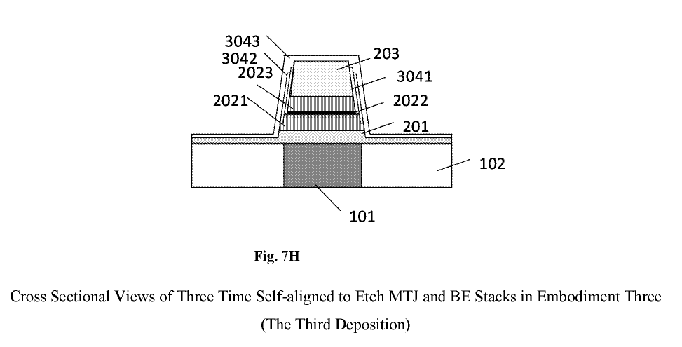

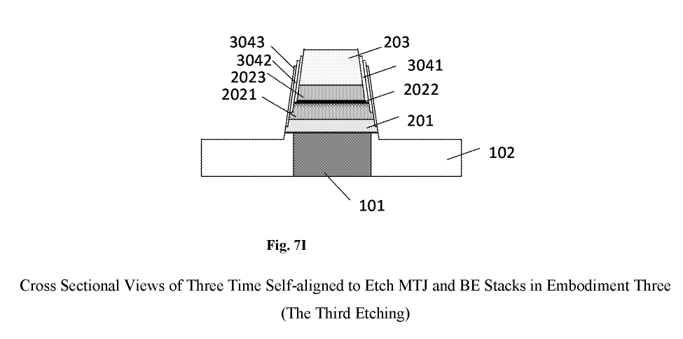

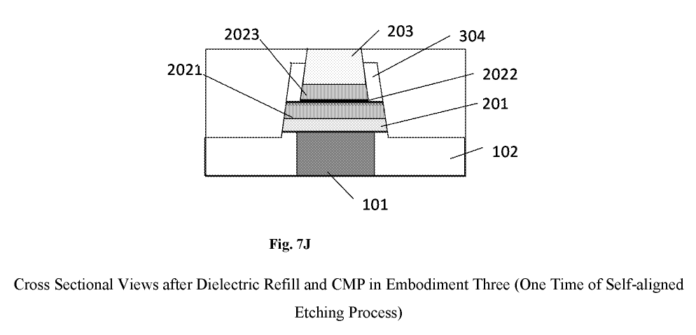

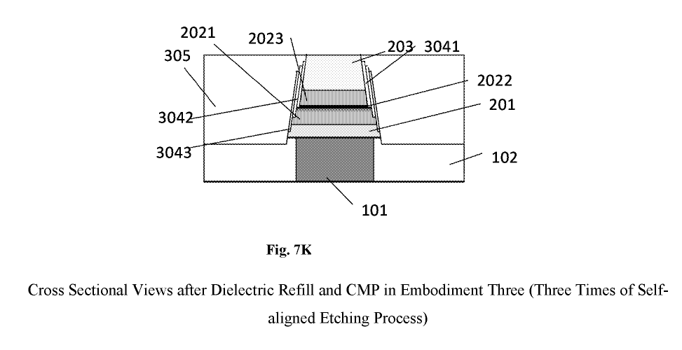

Following from the above HM stack (203) etch process, as shown in FIG. 7A, the MTJ stack (202) is partially etched and the etching is stopped at the oxide tunnel barrier layer (2022) by using an endpoint detection.

The etchant of MTJ stack (202) RIE could be selected from CO/NH3, CH3OH, CH3OH/Ar or C2H5OH; The endpoint trigger signal could be selected from OES or SIMS which could help determine ending of etching using the changed signal at the tunnel barrier layer (2022).

Next, as shown in FIGS. 7B, 7C, 7D, 7E, 7F, 7G, 7H and 7I, the remaining un-etched portion of the MTJ stack (202) and BE stack (201) are etched using one or more of RIE and/or IBE processes with Ta & sidewall protection layer on top portion of MTJ as hard mask (self-aligned etching process). A thin layer of IMD (101) under BE stack (201) should be etched away to prevent the electrical shorting between the bottom electrodes nearby.

The self-aligned etching process of the remaining un-etched MTJ stack (202) and BE stack (201) is divided into two sub-processes (1) Deposition: deposit a protection layer to conformally cover the etched Ta HM (203), MTJ stack (202) and/or BE (201) stack using CVD or ALD; (2) Etching: etch the bottom of protection layer, un-etched MTJ stack (202), and/or un-etched BE stack (201) using IBE or RIE; The (1) Deposition/(2) Etching flow could be repeated until the exposed BE is completely etched away.

The protection layer is a dielectric, such us: SiO2, SiON, SiN, SiCN, SiC, MgO or Al2O3; The thickness is between 2 nm and 50 nm.

The RIE etch process is taken place in an Inductively Coupled Plasma (ICP) or Capacitively Coupled Plasma (CCP) chamber with a high precise controllable vacuum range from 1 mTorr to 100 mTorr; The source power is adjusted from 200 watt to 3000 watt, the bias power is adjusted from 100 watt to 1500 watt; The main etchant of RIE could be selected from CH4/H2, CO/NH3, CH3OH or C2H5OH with the gas flow rate from 5 sccm to 100 sccm, optionally, the RIE etchant could be also added by some other chemistries, such us: Ar, Kr and Xe etc., with the gas flow rate from 10 sccm to 200 sccm; The temperature range of Electrostatic Chuck (ESC) is from 20° C. to 300° C. which could be used for wafer temperature controlling.

The Ion beam in the IBE could be selected as perpendicular or tilted to the wafer substrate, such us: 5° or 10°; The ion beam gas could be selected from Ar, Ke or Xe etc., with the gas flow rate from 10 sccm to 200 sccm, such us: 10 sccm, 30 sccm, 50 sccm, 100 sccm or 200 sccm, additionally, small flow rate N2 or O2 could be also further added into the etch chemistry; The source power is adjusted from 100 watt to 3000 watt, the acceleration voltage is adjusted from 50 volt to 1000 volt; The rotation speed of wafer stage is from 0 rpm to 60 rpm, such us: 0 rpm, 30 rpm or 60 rpm.

The etching endpoint trigger signal could be selected from OES or SIMS which could help determine ending of etching using the changed signal at the interface of BE (201) and IMD (101).

An exemplary embodiment of remaining MTJ stack (202) and BE stack (201) using self-aligned etching process is described as below: (1) Deposition: as shown in FIG. 7B, deposit a protection layer (304) to conformally cover the etched Ta HM (203) and MTJ stack (202); (2) Etching: as shown in FIG. 7C, etch the bottom of protection layer (303), un-etched MTJ stack (202) and BE stack (201) with some IMD (101) be etched away.

Another embodiment of etching remaining MTJ stack (202) and BE stack (201) using self-aligned etching process is described as below: (1) The first Deposition: as shown in FIG. 7D, deposit a first protection layer (3041) to conformally cover the etched Ta HM (203) and MTJ stack (202); (2) The first Etching: as shown in FIG. 7E, etch the bottom of first protection layer (3041) and remaining MTJ stack (202); (3) The second Deposition: as shown in FIG. 7F, deposit a second protection layer (3042) to conformally cover the etched Ta HM (203), MTJ stack (202) and un-etched first protection layer (3041); (4) The second Etching: as shown in FIG. 7G, etch the bottom of second protection layer (3042) and the un-etched MTJ stack (202) and BE stack (201); (5) The third Deposition: as shown in FIG. 7H, deposit a third protection layer (3043) to conformally cover the etched Ta HM (203), etched MTJ stack (202), BE stack (201), un-etched first protection layer (3041) and un-etched second protection layer (3042); (4) The third Etching: as shown in FIG. 71, etch the bottom of third protection layer (3043) and the un-etched BE stack (201) with some IMD (101) be etched away.

Finally, as shown in FIGS. 7J and 7K, a dielectric layer (305) is refilled in the etched area of Ta HM (203), MTJ (202) and BE (201) using CVD technology with SiN, SiO2 or SiON, after that, the dielectric layer (305) is polished to the top of Ta HM layer (203) using CMP technology.

One should realize that etch stop at the oxide tunneling barrier has an advantage of having a wider magnetic reference (pinning) stack layer with balanced magnetization, which could prevent any magnetic disturbance to the etched memory layer nearby.

1. A method of manufacturing a magnetic random access memory array with small footprint comprising:
forming a bottom electrode (BE) stack element;
forming a magnetic tunneling junction (MTJ) stack element above the BE;
forming a hard mask (HM) stack element above the MTJ;
forming a photoresist (PR) stack element above the HM;
patterning the MTJ using UV photolithography;
etching the HM stack element using PR stack as mask;
etching the MTJ stack element using the HM stack as mask;
etching the BE stack element using the HM stack as mask; and
refilling the etched area of MTJ and BE with dielectric materials.

2. The method of claim 1, wherein forming a BE comprises forming a seed layer such as Ta, TaN, Ti or TiN, a main conducting layer such as Cu, CuN, Ru, Mo or W and a capping layer such as Ta, TaN, W or WN.

3. The method of claim 1, wherein forming a MTJ stack comprises forming a magnetic reference element such as [X/Co]nRuCo[X/Co]m/Y/CoFeB/where X is selected from Pt, Pd or Ni and Y is selected from Ta, W, or Mo, an oxide tunnel barrier layer such as MgO or MgZnO, and magnetic memory element such as CoFeB and/or CoFe, or a reversed stack of magnetic memory, tunnel barrier and reference elements.

4. The method of claim 1, wherein forming a HM stack comprises forming a Ta single layer, a Ta/Si-dielectric bi-layer, or Ta/C/Si-dielectric tri-layer.

5. The method of claim 1, wherein forming a PR stack comprises forming a BARC/PR bi-layer or OPL/ARC/PR tri-layer, wherein PR refers to a photo resist, BARC refers to a bottom antireflection coat (ARC), OPL refers an organic planarization layer.

6. The method of claim 1, wherein patterning the MTJ comprises using a single litho-etch (LE) or double litho-etch (LELE) process.

7. The method of claim 1, wherein etching the HM stack element comprises using a series of reactive ion etch using Fluorine (such as CF4 or SF6) or C12 based gases for Ta and Si-dielectric, and oxygen for C layer.

8. The method of claim 1, wherein etching the MTJ stack comprises using one or more of reactive ion etching (RIE) process and/or ion-beam etch (IBE) process, using Ta as a hard mask.

9. The method of claim 8 wherein the RIE process comprises using one or more of a main etchant gas methanol (CH3OH), ethanol, and a mixture of CO and NH4 or CH4 and H2.

10. The method of claim 8 wherein the IBE process comprises using one or more of Ar, Kr or Xe as main etch gases.

11. The method of claim 1, wherein etching the BE stack element comprises using one or more of reactive ion etching (RIE) process and/or ion-beam etch (IBE) process, through self-alignment with MTJ stack using Ta as a hard mask.

12. The method of claim 1, wherein etching the MTJ comprises using a capping layer adjacent to the BE.

13. The method of claim 1, wherein etching the MTJ further comprises trimming exposed edges of a post-etched MTJ by a low energy IBE to remove re-deposition and/or etch-damaged dead layers.

14. The method of claim 1, wherein refilling the etched area of MTJ and the BE with dielectric materials comprises using a chemical vapor deposition (CVD) or atomic layer deposition (ALD).

15. The method of claim 1, wherein etching the BE comprises applying RIE and/or IBE using Ta & protection layer on MTJ as a mask through self-alignment.

16. The method of claim 1, wherein etching the MTJ further comprises using an end-point detection control for terminating etching at the tunnel barrier layer (MgO or MgZnO) .

17. The method of claim 1, wherein refilling the etched area of MTJ with dielectric materials comprises using a CVD or ALD on edges of a partially-etched MTJ.

18. The method of claim 1, wherein etching the MTJ and etching the BE comprise applying RIE and/or IBE on remaining un-etched MTJ layers and BE stack in process using Ta & protection layer on top portion of MTJ as a mask through self-alignment.

19. The method of claim 1, wherein etching the BE stack element and refilling the etched area of MTJ and BE with dielectric materials can be one time or repeated several times until the BE is completely etched without damaging the exposed MTJ junction.

20. The method of claim 1, wherein refilling the etched area of MTJ and BE with dielectric materials comprise using a materials selected from SiO2, SiON, SiN, SiCN, SiC, MgO or Al2O3.
